(19) United States
(12) Patent Application Publication
(10) Pub. No.: US 2008/0143323 A1
(43) Pub. Date: Jun. 19, 2008

(54) Method of detecting rotational position by using hall element and hall element resolver

(76) Inventor: Akira Akahane, Nagano-ken (JP)

Correspondence Address: FLYNN THIEL BOUTELL & TANIS, P.C., 2026 RAMBLING ROAD, KALAMAZOO, MI, 49008-1631, US

(21) Appl. No.: 11/978,284

(22) Filed: Oct. 29, 2007

(30) Foreign Application Priority Data
Dec. 18, 2006 (JP) 2006-340434

(51) Int. Cl. G01R 33/07

(52) U.S. Cl. 324/207.2

(57) ABSTRACT

In a hall element resolver (10), a pair of hall elements (13, 23) are placed so as to generate detection signals, which include a phase difference of 90 degrees and are sine-curved, when a rotary magnetic drum magnetized with two poles rotates. Meanwhile, supplied as control currents Ic₁ and Ic₂ for driving the hall elements (13, 23) are alternate electric currents, which include a phase difference of 90 degrees and have the identical frequency, and balanced modulation signals, which include a phase difference of 90 degrees and are sine-curved, are output from the hall elements (13, 23) as detection signals V_{H1} and V_{H2}. Then, a rotational position is calculated according to the balanced modulation signals. Thus, it is possible by using the hall elements to obtain detection signals which have resistance to a noise, and with which a transmission distance can be lengthened, as it is done by using a resolver.

### FIELD OF THE INVENTION

The present invention relates to a method of detecting a rotational position, through which a rotational position of a turning shaft is detected by using a pair of hall elements to generate detection signals in the same manner as a resolver does, and a hall element resolver using the method of the same.

### BACKGROUND OF THE INVENTION

As a mechanism for detecting a rotational position of a turning shaft such as a turning shaft of a motor and so on, commonly known is a sine-cosine-output type hall element sensor having a pair of hall elements. As shown in FIG. 1A and FIG. 1B, a detecting section of the sensor includes; a rotary magnetic drum 2 which is magnetized with two poles and coaxially fixed to a turning shaft 1 of a detection object, and a pair of hall elements 3 and 4 which are placed so as to generate detection signals having a phase difference of 90 degrees when the rotary magnetic drum 2 rotates.

The hall elements 3 and 4 are supplied with a control current Ic having a constant value for a driving operation from a constant-voltage circuit or a constant-current circuit 5, as shown in FIG. 2. Therefore, as shown in FIG. 3; detection signals (hall voltage values V_{H1} and V_{H2}), which are sine-curved and have a phase difference of 90 degrees, are output from each of the hall elements 3 and 4 when the rotary magnetic drum 2 rotates. The detection signals having two phases are transmitted to a signal processing circuit 6 through a transmission line. Then, the detection signals are amplified and digitized in the signal processing circuit 6; and subsequently an arithmetical operation is carried out for the detection signals to calculate an absolute position within one revolution, the count number of revolutions by referring to an origin position as a standard, and so on.

By the way, a magnetic encoder including a pair of hall elements is disclosed, for example, in Patent Document 1 through Patent Document 3.

### [Patent Document 1]

JP-A 2006-208025

### [Patent Document 2]

JP-A 2005-140737

### [Patent Document 3]

JP-A 2005-172720

Unfortunately, the sensor provided with a structure described above has problems described as follows. That is to say; at first, since a detection signal of each hall element is an analog output, a noise is easily mixed into the signal so that it is impossible to improve an S/N ratio. Furthermore, because of the same reason, a transmission distance between the hall element and a digital converter, which digitizes the detection signal output from the hall element for signal processing, cannot be lengthened. Moreover, if the detection signal of the hall element is A/D-converted as it is, a resolution cannot be improved.

### DISCLOSURE OF THE INVENTION

In view of the problems described above, it is an object of the present invention to propose a method of detecting a rotational position by using hall elements which has resistance to a noise and obtains a detection signal that is able to lengthen a transmission distance, as it is done by using a resolver.

To solve the problems described above, a method of detecting a rotational position by using hall elements relating to the present invention includes: placement of a pair of hall elements so as to generate detection signals, which include a phase difference of 90 degrees and are sine-curved, when a rotor magnetized with multiple poles rotates; supplying alternate electric currents, which include a phase difference of a ¼ cycle and have the identical frequency, as control currents for driving the hall elements; outputting balanced modulation signals, which include a phase difference of 90 degrees and are sine-curved, as detection signals from the hall elements, when the rotor rotates; and calculating a rotational position of the rotor according to the balanced modulation signals. On this occasion, a rotary disc magnetized with two poles may be used as the rotor.

In the present invention, since alternate electric currents having a prescribed frequency are used as the control currents for the hall elements, the detection signals of the hall elements are able to be balanced modulation signals that are sine-curved. Therefore, it is possible to materialize a method of detecting a rotational position by using hall elements provided with an advantage that the method has resistance to a noise, and a transmission distance can be lengthened with the method, as it is done with a resolver.

### BRIEF DESCRIPTION OF THE DRAWINGS

FIG. 1A and FIG. 1B are structural drawings showing a detecting section of a sine-cosine-output type hall element sensor.

FIG. 2 is an outline structural drawing of a conventional sine-cosine-output type hall element sensor.

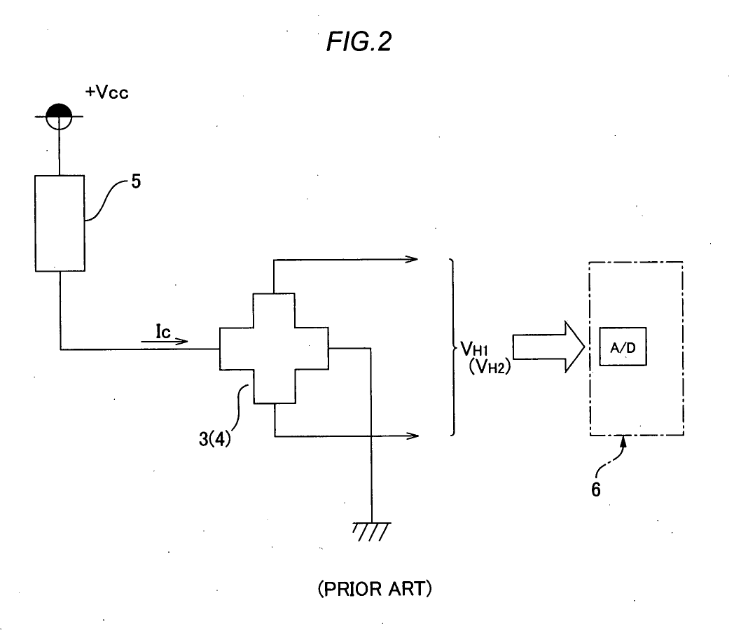

FIG. 3 is a drawing of signal waves showing detection signals of hall elements.

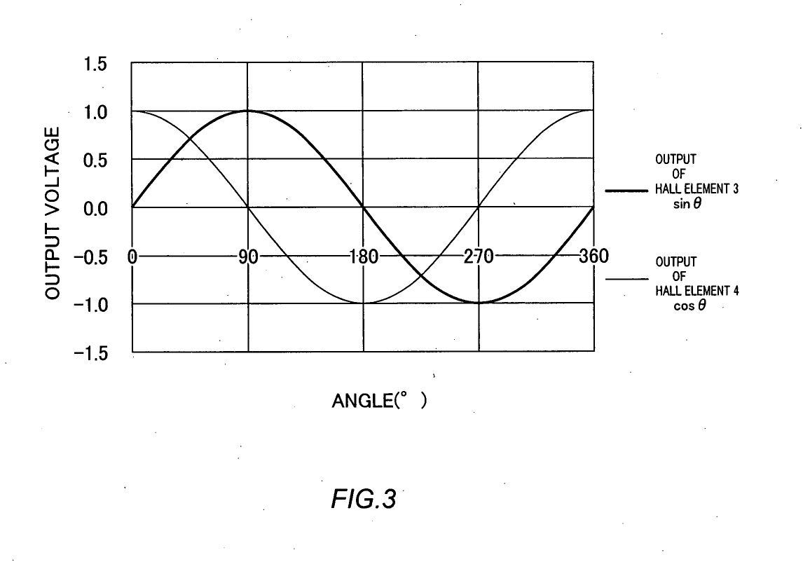

FIG. 4 is an explanatory drawing of a hall element resolver in which the present invention is applied.

FIG. 5 is a drawing of signal waves at various positions of the hall element resolver shown in FIG. 4.

FIG. 6 is a drawing of signal waves that shows hall element outputs of the hall element resolver shown in FIG. 4.

FIG. 7 is a drawing of a signal wave that shows a relationship between a difference signal and an alternate voltage of a hall element output.

### DESCRIPTION OF THE PREFERRED EMBODIMENTS

Described below with reference to the accompanying drawings is an embodiment to which the present invention is adopted.

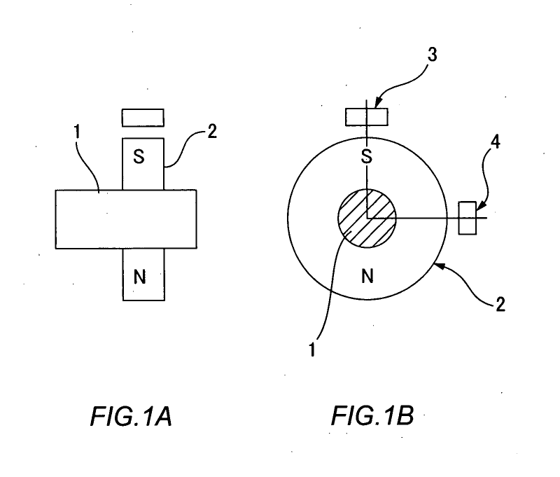

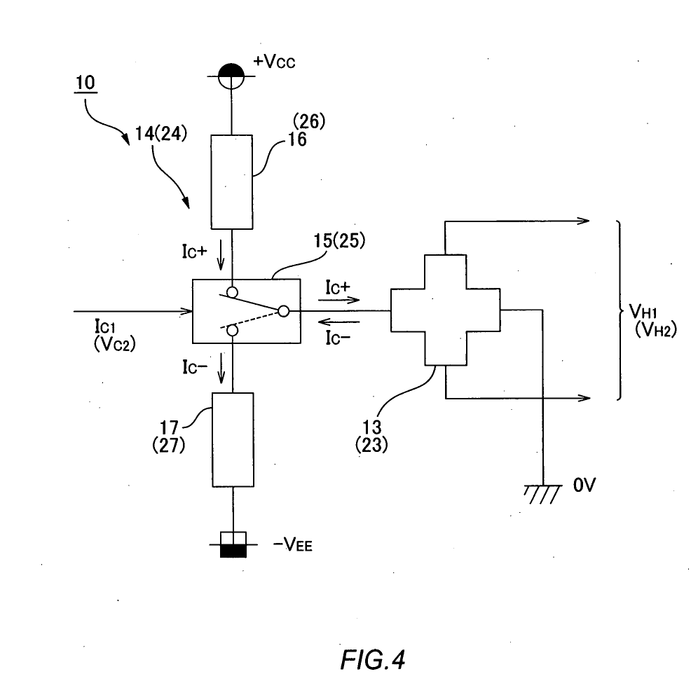

FIG. 4 is an outline structural drawing that shows a detecting section of a hall element resolver to which a method of the present invention is adopted. In the same manner as shown in FIG. 1, a hall element resolver 10 includes; a rotary magnetic drum which is magnetized with two poles and coaxially fixed to a turning shaft of a detection object, and a pair of hall elements 13 and 23 which are placed so as to generate detection signals having a phase difference of 90 degrees when the rotary magnetic drum rotates.

A control current Ic₁ to be supplied to the hall element 13 is an alternate current that switches a current direction at a certain frequency “f”. That is to say; a hall element drive circuit 14 includes; an analog switch 15 and a pair of constant-current circuits 16 and 17. Then, the analog switch 15 carries out a switching operation with an alternate voltage Vc₁ having the certain frequency “f” (=ω/2π) so that a hall element 13 is supplied with an alternate current that switches to be positive and negative alternately with the frequency “f”.

A control current Ic₂ to be supplied to the hall element 23 is also an alternate current that switches a current direction at a certain frequency “f”. That is to say; a hall element drive circuit 24 includes; an analog switch 25 and a pair of constant-current circuits 26 and 27. Then, the analog switch 25 carries out a switching operation with an alternate voltage Vc₂ having the certain frequency “f” (=ω/2π) so that a hall element 23 is supplied with an alternate current that switches to be positive and negative alternately with the frequency “f”. Thus, the control current Ic₁ and the control current Ic₂, to be supplied to the hall element 23 and the hole element 24, respectively, are provided with a phase difference of a ¼ cycle.

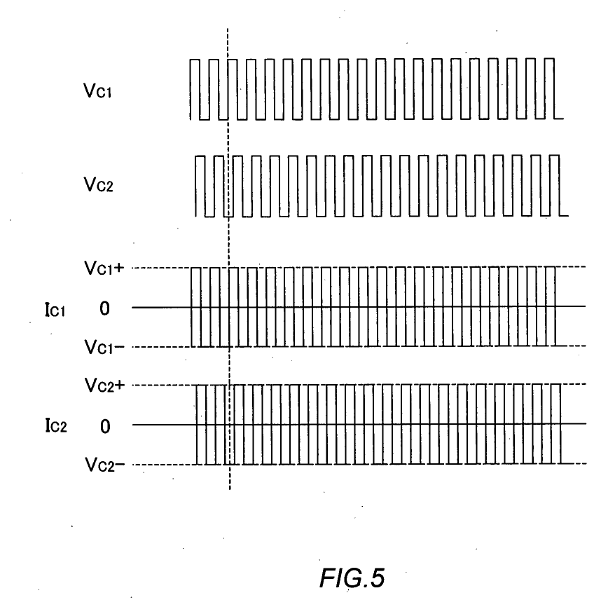

Shown in FIG. 5 are waveforms of the alternate voltages (control voltages) Vc₁ and Vc₂ as well as the control currents Ic₁ and Ic₂ which are imposed on the analog switches 15 and 25.

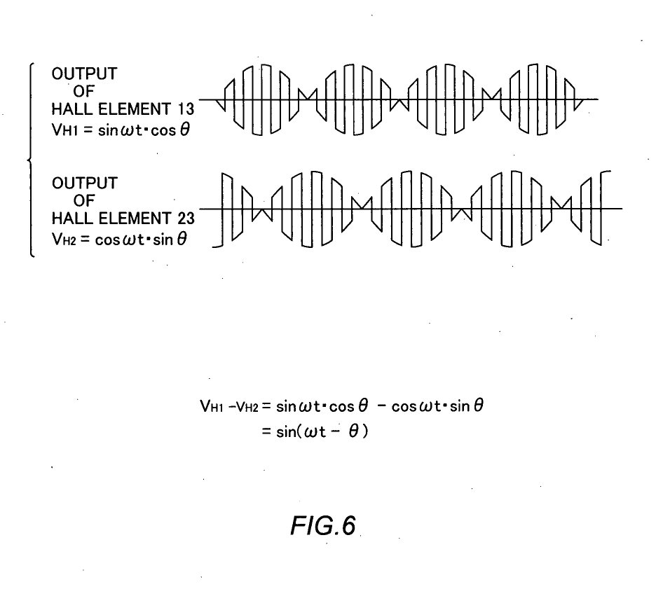

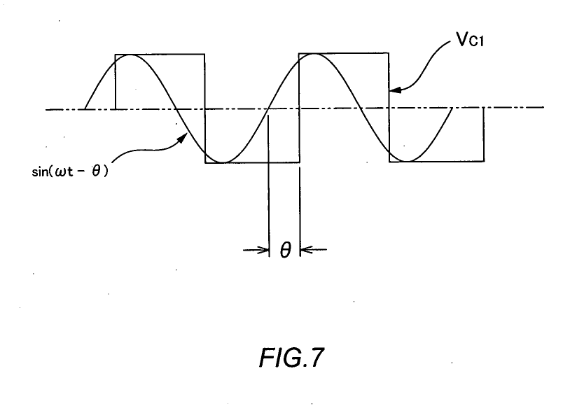

Through imposing the alternate currents that switch to be positive and negative alternately with the frequency “f” as control currents, the detection signals V_{H1} and V_{H2} of the hall elements 13 and 23 become balanced modulation signals, as shown in FIG. 6. Then, as a result of subtraction between the detection signal V_{H1}(=sin ωt·cos θ) and the detection signal V_{H2}(=cos ωt·sin θ), obtained there is a signal which has the same frequency as the control voltage Vc₁ has, and whose phase is shifted for a rotation angle θ of the rotary magnetic drum as shown in FIG. 7:

$$\begin{matrix}{V}_{H 1} - {V}_{H 2} = sin ω t \cdot cos θ - cos ω t \cdot sin θ \\ = sin ( ω t - θ )\end{matrix}$$

Therefore, the rotation angle θ can be obtained as a digital value by counting the angle interval θ with a clock signal. To the contrary, the rotation angle θ can be obtained as an analog voltage through phase detection of the angle interval θ.

As described above, in the hall element resolver 10 of the present example; the control currents Ic₁ and Ic₂ of the hall elements 13 and 23 are alternated at a high frequency (from several thousand Hz to several ten thousand Hz) so that the detection signals V_{H1} and V_{H2} of the hall elements 13 and 23 become balanced modulation signals having a sine waveform and a cosine waveform. As a result, the detection signals obtained are equivalent to what a standard resolver gives, and therefore it is possible to bring about an effect that the detection signals have resistance to a noise and a transmission distance can be lengthened, as it is done with a resolver.

1. A method of detecting a rotational position by using hall elements comprising:
placing a pair of hall elements so as to generate detection signals, which include a phase difference of 90 degrees and are sine-curved, when a rotor magnetized with multiple poles rotates;
supplying alternate electric currents, which include a phase difference of a ¼ cycle and have an identical frequency, as control currents for driving the hall elements;
outputting balanced modulation signals, which include a phase difference of 90 degrees and are sine-curved, as detection signals from the hall elements, when the rotor rotates; and
calculating a rotation angle of the rotor according to the balanced modulation signals.

2. The method of detecting a rotational position by using hall elements according to claim 1:
wherein a rotary disc magnetized with two poles is used as the rotor.

3. A hall element resolver characterized by detecting a rotation angle of a rotor according to the method of claim 1.
